(19) United States
(12) Patent Application Publication
(10) Pub. No.: US 2026/0161072 A1
(43) Pub. Date: Jun. 11, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Sangkyun IM, Suwon-si (KR); Young Keun KIM, Suwon-si (KR); Sungil MOON, Suwon-si (KR); Jun SAKONG, Suwon-si (KR)

(21) Appl. No.: 19/182,073

(22) Filed: Apr. 17, 2025

(30) Foreign Application Priority Data
Jun. 27, 2024 (KR) 10-2024-0084737

(51) Int. Cl. G03F 7/004; H10P 50/00; H10P 76/20

(52) U.S. Cl. CPC G03F 7/0042; H10P 50/71; H10P 50/73; H10P 76/2042

(57) ABSTRACT

A semiconductor photoresist composition includes an organometallic compound represented by Chemical Formula 1 and a solvent. A method of forming patterns utilizes the semiconductor photoresist composition.

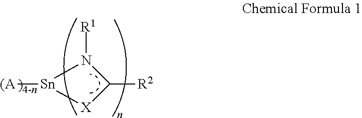

### CROSS-REFERENCE TO RELATED APPLICATION

The present application claims priority to and the benefit of Korean Patent Application No. 10-2024-0084737, filed on Jun. 27, 2024, in the Korean Intellectual Property Office, the entire content of which is incorporated herein by reference.

### BACKGROUND

### 1. Field

This disclosure relates to a semiconductor photoresist composition and a method of forming patterns using the same.

### 2. Description of the Related Art

Extreme ultraviolet (EUV) lithography has gained attention as an important (e.g., essential) technology for manufacturing a next generation semiconductor device. EUV lithography is a pattern-forming technology that uses an EUV ray with a wavelength of 13.5 nm as an exposure light source. In EUV lithography, extremely fine patterns (e.g., less than or equal to 20 nm) may be formed through an exposure process during the manufacturing of semiconductor devices.

The realization of extreme ultraviolet (EUV) lithography depends on development of compatible photoresists that can achieve a spatial resolution of less than or equal to 16 nm. Currently, efforts are underway to address the limitations of related art chemically amplified (CA) photoresists, such as in resolution, photospeed, and/or feature roughness (also referred to as a line edge roughness or LER), to meet the specifications for the next generation device.

Intrinsic image blurring due to an acid catalyzed reaction in these polymer-type (kind) photoresists limits a resolution in small feature sizes, a phenomenon known in electron beam (e-beam) lithography. The chemically amplified (CA) photoresists are designed for high sensitivity, but their typical elemental makeups reduce light absorbance of the photoresists at a wavelength of 13.5 nm and thus decrease their sensitivity under EUV exposure.

In addition, the CA photoresists may have difficulties with small feature sizes due to roughness issues. Experimental results show that line edge roughness (LER) increases as photospeed decreases partially due to inherent characteristics of acid catalyst processes. Accordingly, a novel high-performance photoresist is desired or required in the semiconductor industry to address these defects and problems of the CA photoresists.

In order to overcome the drawbacks of the chemically amplified (CA) organic photosensitive composition, research has been conducted on inorganic photosensitive compositions. These inorganic photosensitive compositions are mainly used for negative tone patterning and have resistance against removal by a developer composition due to chemical modification through a nonchemical amplification mechanism. Inorganic compositions contain elements with higher EUV absorption rates than hydrocarbons, and thus may secure or ensure suitable sensitivity through the nonchemical amplification mechanism. Additionally, inorganic compositions are less sensitive to stochastic effects and may have low line edge roughness and fewer defects.

Inorganic photoresists based on peroxopolyacids of tungsten mixed with tungsten, niobium, titanium, and/or tantalum have been reported as radiation sensitive materials for patterning (see also, U.S. Pat. No. 5,061,599; and H. Okamoto, T. Iwayanagi, K. Mochiji, H. Umezaki, T. Kudo, Applied Physics Letters, 49(5), 298-300, 1986, the entire content of each of which is incorporated herein by reference).

These materials are effective for patterning large pitches for bilayer configuration as far ultraviolet (deep UV), X-ray, and electron beam sources. More recently, cationic hafnium metal oxide sulfate (HfSOx) materials along with a peroxo complexing agent has been used to image a 15 nm half-pitch (HP) through projection EUV exposure, and impressive performance has been obtained (see also, US 2011-0045406; and J. K. Stowers, A. Telecky, M. Kocsis, B. L. Clark, D. A. Keszler, A. Grenville, C. N. Anderson, P. P. Naulleau, Proc. SPIE, 7969, 796915, 2011, the entire content of each of which is incorporated herein by reference). This system exhibits better performance as a non-CA photoresist and has a practicable photospeed close to the requirement for an EUV photoresist. However, the hafnium metal oxide sulfate material having the peroxo complexing agent has a few practical drawbacks. First, these materials are coated in a mixture of corrosive sulfuric acid/hydrogen peroxide and may have insufficient shelf-life stability. Second, as a composite mixture, a structural change thereof for performance improvement is not easy. Third, development has to be performed in a tetramethylammonium hydroxide (TMAH) solution at a high (e.g., extremely high) concentration of 25 wt % and/or the like.

Recently, active research has been conducted on molecules (e.g., materials) containing tin, which have excellent or suitable absorption of extreme ultraviolet rays. Among these, organotin polymers dissociate alkyl ligands by light absorption or secondary electrons, crosslinking with adjacent chains through oxo bonds to enable negative tone patterning that resists removal by an organic developer. This organotin polymer exhibits greatly improved sensitivity while maintaining suitable resolution and line edge roughness, but the patterning characteristics need further improvement for commercial availability.

### SUMMARY

An aspect according to some embodiments is directed toward a semiconductor photoresist composition having (with) improved coatability and storage stability, while maintaining excellent or suitable sensitivity characteristics.

An aspect according to some embodiments is directed toward a method of forming patterns using the semiconductor photoresist composition.

Additional aspects will be set forth in part in the description which follows and, in part, will be apparent from the description, or may be learned by practice of the presented embodiments of the disclosure.

A semiconductor photoresist composition according to some embodiments includes an organometallic compound represented by Chemical Formula 1 and a solvent.

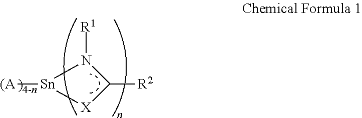

In Chemical Formula 1,

A may be selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X may be O or S,
R¹ and R² may each independently be selected from among hydrogen, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C6 to C30 aryl group, a substituted or unsubstituted C7 to C30 arylalkyl group, and L-Z—R³ (wherein L is a substituted or unsubstituted C1 to C20 alkylene group, Z is O, S, or NR⁴, wherein R³ and R⁴ may each independently be a C1 to C20 alkyl group), and
n may be an integer of 2 or 3.

A method of forming patterns according to some embodiments includes forming an etching-objective layer on a substrate, coating the semiconductor photoresist composition on the etching-objective layer to form a photoresist layer, patterning the photoresist layer to form a photoresist pattern, and etching the etching-objective layer using the photoresist pattern as an etching mask.

The semiconductor photoresist composition according to some embodiments can improve surface roughness by enhancing coating properties and provide a photoresist pattern with improved moisture and heat stability.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIGS. 1A-1E are cross-sectional views for explaining a method of forming patterns using a semiconductor photoresist composition according to some example embodiments.

### DETAILED DESCRIPTION

Hereinafter, referring to the drawings, embodiments are described in more detail. In the following description of the present disclosure, the functions or constructions known in the related art will not be described in order to clarify the present disclosure.

Throughout the disclosure, the same or similar configuration elements are designated by the same reference numerals. Also, because the size and thickness of each configuration shown in the drawing are arbitrarily shown for better understanding and ease of description, the present disclosure is not necessarily limited thereto.

In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element such as a layer, film, region, or substrate is referred to as being “on” another element, it can be directly on the other element or intervening elements may also be present.

As used herein, the term “substituted” refers to replacement of a hydrogen atom by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, and/or a (e.g., any suitable) combination thereof. The term “unsubstituted” refers to non-replacement of a hydrogen atom by another substituent and remaining as the hydrogen atom.

As used herein, if (e.g., when) a definition is not otherwise provided, the term “alkyl group” refers to a linear or branched aliphatic hydrocarbon group. The alkyl group may be “saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, the term “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

As used herein, the term “aryl group” refers to a cyclic substituent in which all atoms in the cyclic substituent have a p-orbital and these p-orbitals are conjugated and may include a monocyclic or fused ring polycyclic (i.e., rings sharing adjacent pairs of carbon atoms) functional group. As used herein, the term “heteroaryl group” may refer to an aryl group including at least one heteroatom selected from among N, O, S, P, and Si. Two or more heteroaryl groups may be linked by a sigma bond directly, or if the heteroaryl group includes two or more rings, the two or more rings may be fused. If the heteroaryl group is a fused ring, each ring may include one to three heteroatoms.

As used herein, unless otherwise defined, the term “alkenyl group” refers to an aliphatic unsaturated alkenyl group including at least one double bond as a linear or branched aliphatic hydrocarbon group.

As used herein, unless otherwise defined, the term “alkynyl group” refers to an aliphatic unsaturated alkynyl group including at least one triple bond as a linear or branched aliphatic hydrocarbon group.

In the chemical formulas described herein, t-Bu refers to a tert-butyl group.

A semiconductor photoresist composition according to some example embodiments is described.

The semiconductor photoresist composition according to some example embodiments includes an organometallic compound represented by Chemical Formula 1 and a solvent.

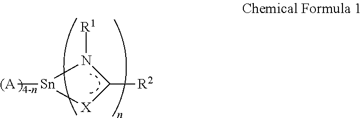

In Chemical Formula 1,
A may be selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X may be O or S,
R¹ and R² may each independently be selected from among hydrogen, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C3 to C20 cycloalkenyl group, a substituted or unsubstituted C6 to C30 aryl group, a substituted or unsubstituted C7 to C30 arylalkyl group, and L-Z—R³ (wherein L is a substituted or unsubstituted C1 to C20 alkylene group, Z is O, S, or NR⁴, wherein R³ and R⁴ may each independently be a C1 to C20 alkyl group), and
n may be an integer of 2 or 3.

The organometallic compound according to the present disclosure can effectively screen (e.g., shield) the Sn atom by including a bidentate chelating ligand having a monovalent charge, thereby increasing the stability of the compound against moisture and heat.

In addition, because both (e.g., simultaneously) intramolecular bonding and intermolecular bonding are possible, the disorder of the thin film formed from the semiconductor photoresist composition may be increased. Also, one or more suitable substituents can be introduced at the two binding sites of the bidentate ligand compared to the single-site (e.g., monodentate) ligand having a single charge, which is more desirable or advantageous in improving surface roughness and forming an amorphous thin film due to improved coatability.

In some embodiments, A may be selected from among a substituted or unsubstituted C1 to C10 alkyl group, a substituted or unsubstituted C2 to C20 heteroalkyl group, a substituted or unsubstituted C3 to C12 cycloalkyl group, a substituted or unsubstituted C2 to C20 heterocycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C2 to C20 heteroaryl group, a substituted or unsubstituted C7 to C20 arylalkyl group, a substituted or unsubstituted C4 to C20 heteroarylalkyl group, and a substituted or unsubstituted C1 to C20 alkylcarbonyl group.

In some embodiments, A may be selected from among a substituted or unsubstituted C1 to C10 alkyl group, a substituted or unsubstituted C3 to C12 cycloalkyl group, a substituted or unsubstituted C2 to C10 alkenyl group, a substituted or unsubstituted C6 to C20 aryl group, and a substituted or unsubstituted C7 to C20 arylalkyl group.

For example, A may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 1-methylpropyl group, a substituted or unsubstituted 1,1-dimethylpropyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, and/or a (e.g., any suitable) combination thereof.

In some embodiments, R¹ and R² may each independently be selected from among hydrogen, a substituted or unsubstituted C1 to C10 alkyl group, a substituted or unsubstituted C2 to C10 alkenyl group, a substituted or unsubstituted C2 to C10 alkynyl group, a substituted or unsubstituted C3 to C12 cycloalkyl group, a substituted or unsubstituted C3 to C12 cycloalkenyl group, a substituted or unsubstituted C6 to C20 aryl group, a substituted or unsubstituted C7 to C20 arylalkyl group, and L-Z—R³ (wherein L is a substituted or unsubstituted C1 to C10 alkylene group, Z is O, S, or NR⁴, wherein R³ and R⁴ may each independently be C1 to C10 alkyl group).

In some embodiments, R¹ and R² may each independently be selected from among hydrogen, a substituted or unsubstituted C1 to C10 alkyl group, a substituted or unsubstituted C3 to C12 cycloalkyl group, a substituted or unsubstituted C2 to C10 alkenyl group, a substituted or unsubstituted C6 to C20 aryl group, and a substituted or unsubstituted C7 to C20 arylalkyl group.

For example, R¹ and R² may each independently be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, and/or a (e.g., any suitable) combination thereof.

The organometallic compound may be selected from among the compounds listed in Group 1.

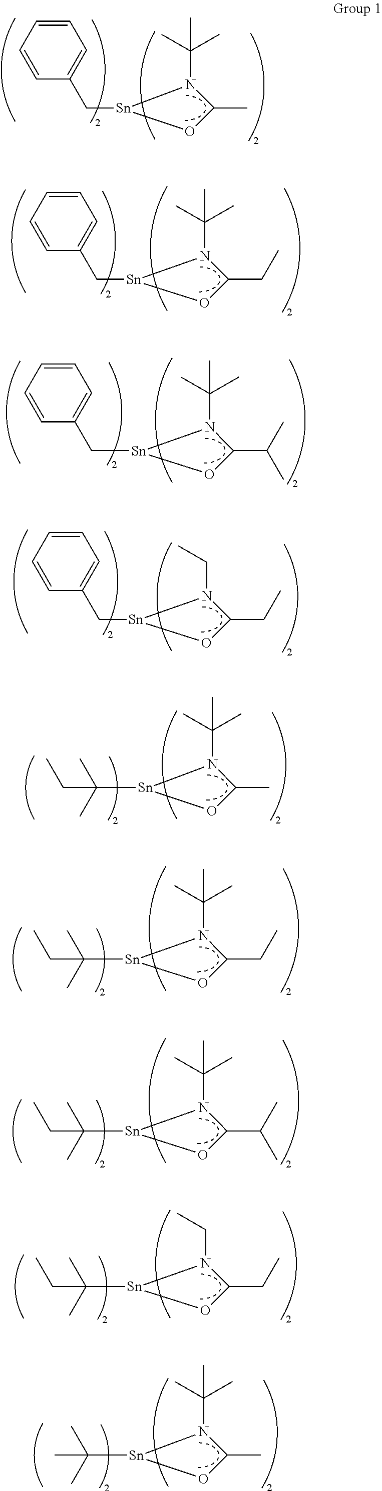

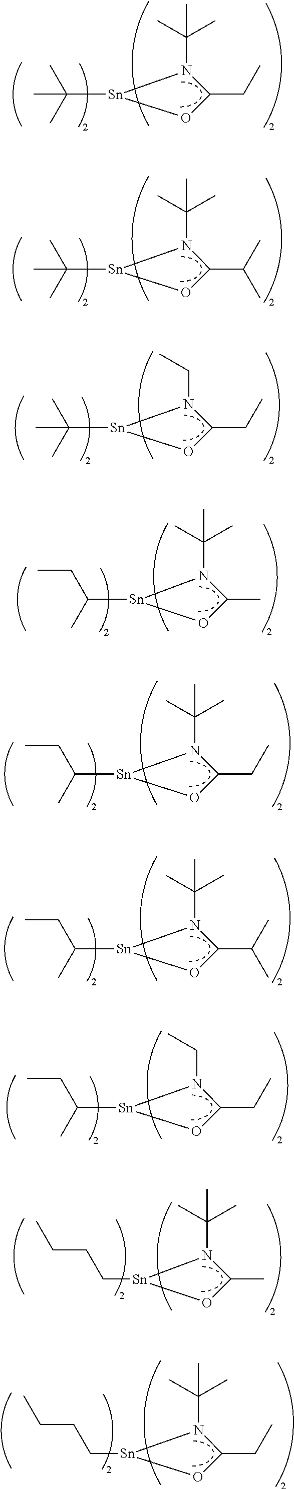

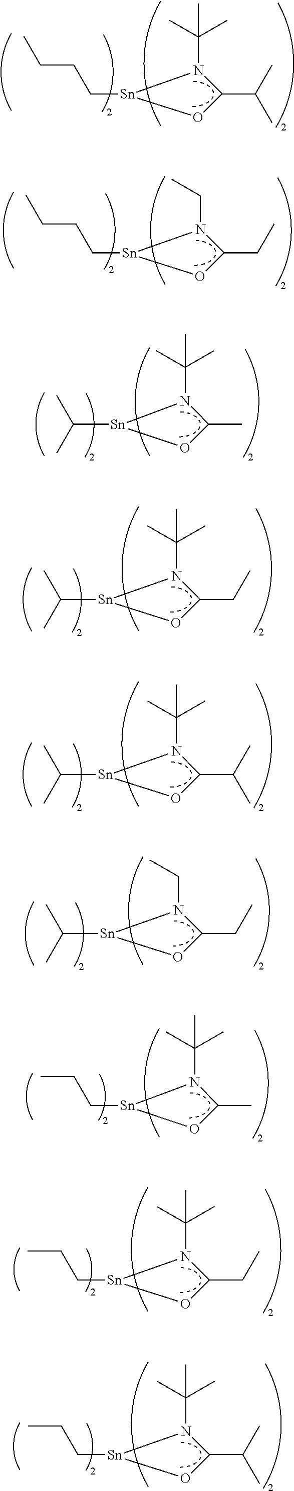

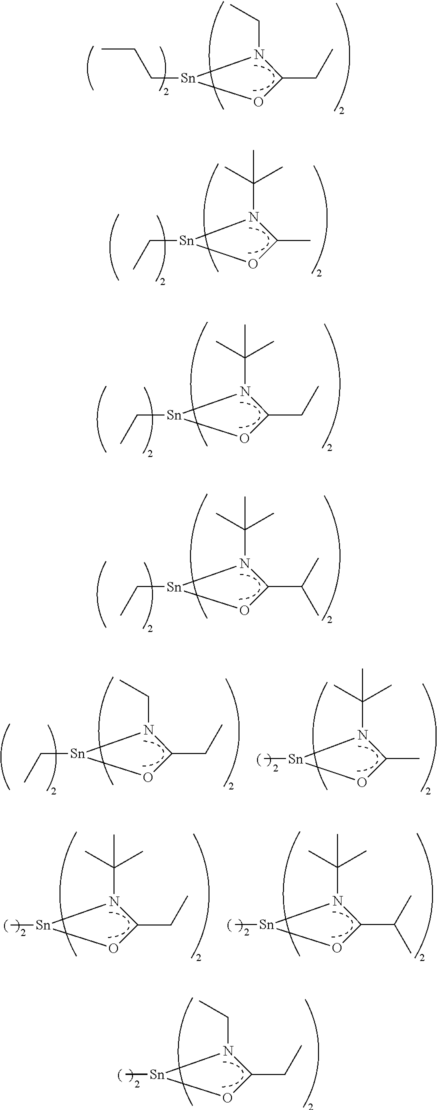

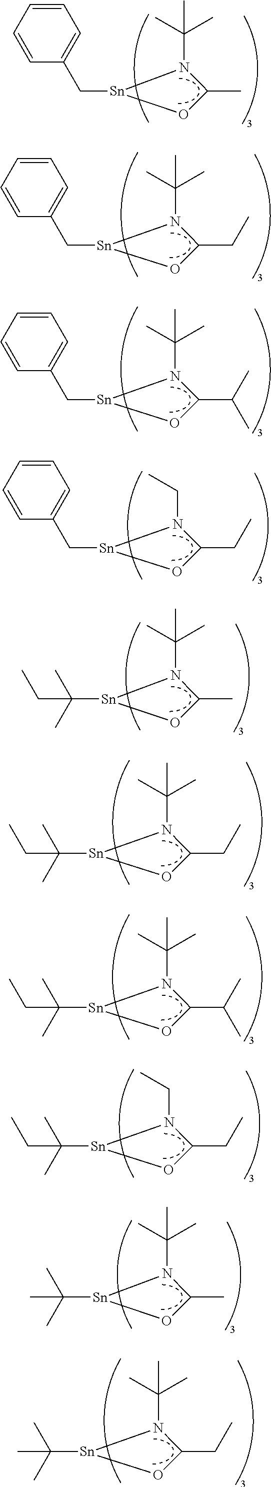

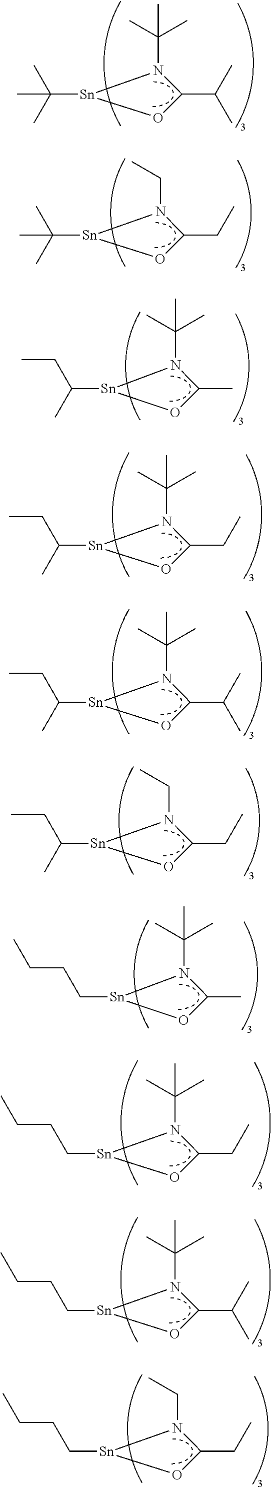

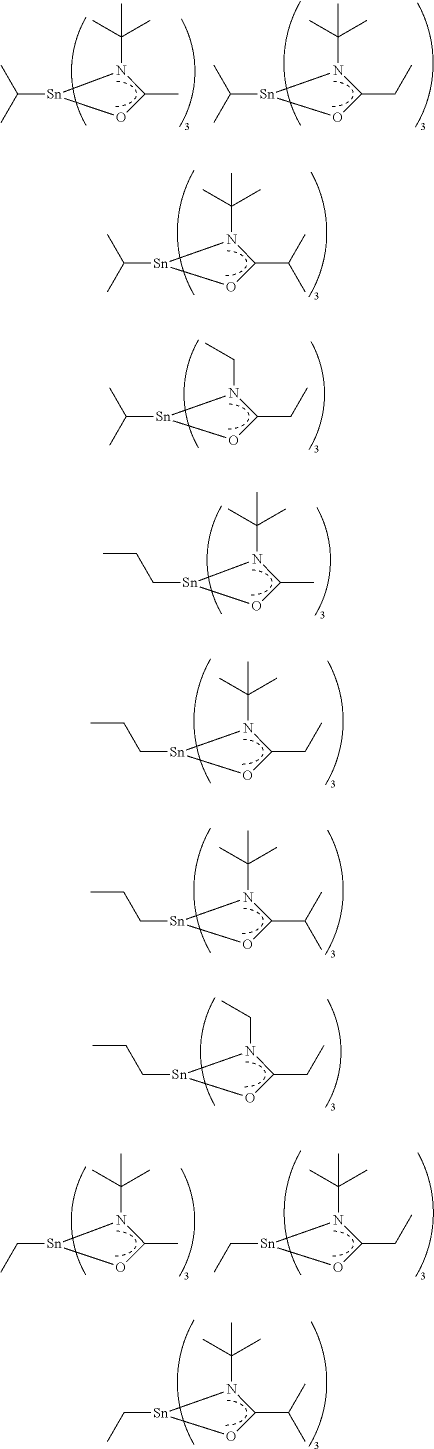

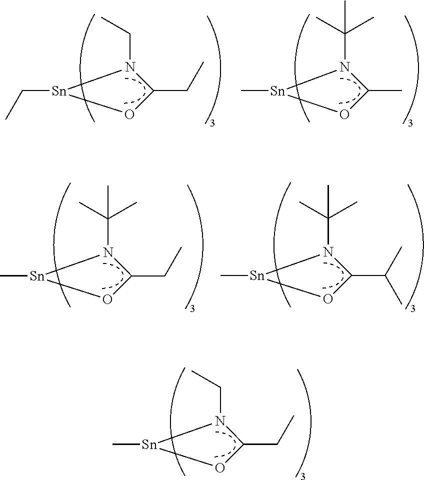

The organometallic compound may absorb extreme ultraviolet light at 13.5 nm suitably or strongly, and thus may have excellent or suitable sensitivity to light with high energy. For example, the organometallic compound may strongly or suitably absorb extreme ultraviolet light at 13.5 nm, providing excellent or suitable sensitivity to high-energy light.

In the semiconductor photoresist composition according to some example embodiments, the organometallic compound may be included in an amount of about 0.5 wt % to about 30 wt %, for example, about 1 wt % to about 30 wt %, about 1 wt % to about 25 wt %, about 1 wt % to about 20 wt %, about 1 wt % to about 15 wt %, about 1 wt % to about 10 wt %, or about 1 wt % to about 5 wt %, based on 100 wt % of the semiconductor photoresist composition, but the present disclosure is not limited thereto. If (e.g., when) the organometallic compound is included in the content (e.g., amount) within the above ranges, the storage stability and etch resistance of the semiconductor photoresist composition are improved, and the resolution characteristics are improved.

A semiconductor photoresist composition according to some example embodiments can provide a semiconductor photoresist composition having excellent or suitable sensitivity and pattern formation properties by including the aforementioned organometallic compound.

The solvent included in the semiconductor photoresist composition according to some example embodiments may be an organic solvent. For example, the solvent may be aromatic compounds (e.g., xylene, toluene, and/or the like), alcohols (e.g., 4-methyl-2-pentanol, 4-methyl-2-propanol, 1-butanol, methanol, isopropyl alcohol, and/or 1-propanol), ethers (e.g., anisole, and/or tetrahydrofuran), esters (n-butyl acetate, propylene glycol monomethyl ether acetate, ethyl acetate, and/or ethyl lactate), ketones (e.g., methyl ethyl ketone, and/or 2-heptanone), and/or a (e.g., any suitable) mixture thereof, but the present disclosure is not limited thereto.

In some example embodiments, the semiconductor photoresist composition may further include a resin in addition to the aforementioned organometallic compound and solvent.

The resin may be a phenolic resin including at least one aromatic moiety listed in Group 2. For example, the resin may be a phenolic resin, including at least one aromatic moiety selected from those listed in Group 2.

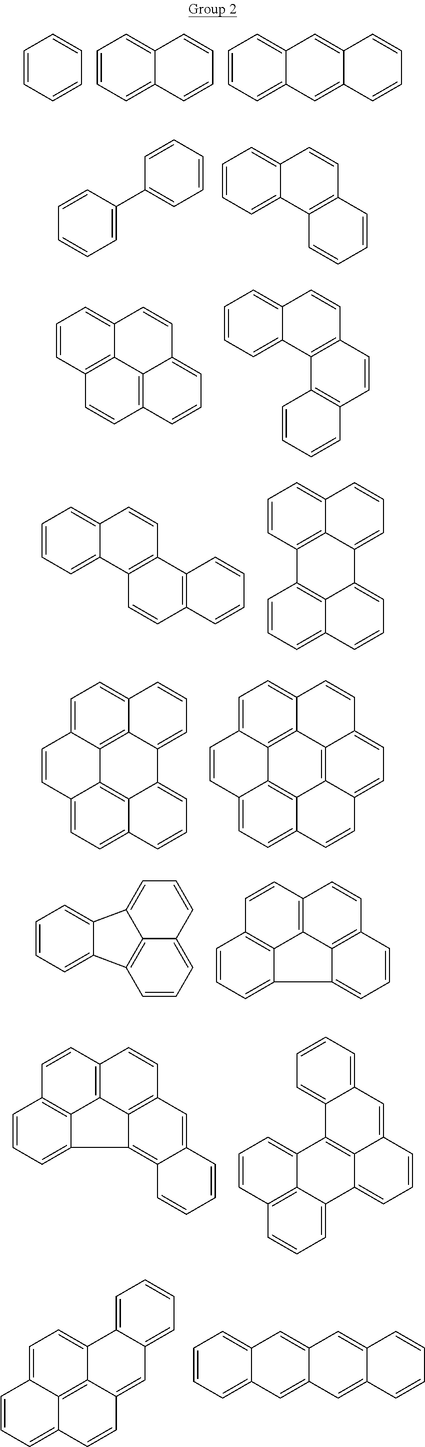

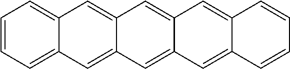 [SMILES: c1ccc2cc3cc4cc5ccccc5cc4cc3cc2c1]

The resin may have a weight average molecular weight of about 500 to about 20,000.

The resin may be included in an amount of about 0.1 wt % to about 50 wt % based on a total 100 wt % of the semiconductor photoresist composition.

If (e.g., when) the resin is included within the above content (e.g., amount) range, the semiconductor photoresist composition can have excellent or suitable etching resistance and heat resistance.

In one or more embodiments, the semiconductor photoresist composition may be composed of the aforementioned organometallic compound, solvent, and resin. However, the semiconductor photoresist composition according to one or more embodiments may further include additives. Examples of the additives may include a surfactant, a crosslinking agent, a leveling agent, an organic acid, a quencher, and/or a (e.g., any suitable) combination thereof.

The surfactant may include for example an alkyl benzene sulfonate salt, an alkyl pyridinium salt, polyethylene glycol, a quaternary ammonium salt, and/or a (e.g., any suitable) combination thereof, but the present disclosure is not limited thereto.

The crosslinking agent may be for example a melamine-based crosslinking agent, a substituted urea-based crosslinking agent, an acryl-based crosslinking agent, an epoxy-based crosslinking agent, or a polymer-based crosslinking agent, but the present disclosure is not limited thereto. The crosslinking agent may have at least two crosslinking forming substituents, for example, the crosslinking agent may be a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and/or a (e.g., any suitable) combination thereof, but the present disclosure is not limited thereto.

The quencher may be diphenyl (p-tolyl) amine, methyl diphenyl amine, triphenyl amine, phenylenediamine, naphthylamine, diaminonaphthalene, and/or a (e.g., any suitable) combination thereof.

An amount of these additives may be controlled or selected depending on desired or suitable properties.

In one or more embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris(β-methoxyethoxy)silane; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but the present disclosure is not limited thereto.

The semiconductor photoresist composition may be formed into a pattern having a high aspect ratio without a collapse (e.g., a pattern that does not collapse). Accordingly, in order to form a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, about 5 nm to about 20 nm, or about 5 nm to about 10 nm, the semiconductor photoresist composition may be used for a photoresist process using light in a wavelength range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some example embodiments may be used to realize extreme ultraviolet lithography using an EUV light source of a wavelength of about 13.5 nm.

According to some example embodiments, a method of forming patterns using the aforementioned semiconductor photoresist composition is provided. For example, the manufactured pattern may be a photoresist pattern.

The method of forming patterns according to some example embodiments includes forming an etching-objective layer on a substrate, coating the semiconductor photoresist composition on the etching-objective layer to form a photoresist layer, patterning the photoresist layer to form a photoresist pattern and etching the etching-objective layer using the photoresist pattern as an etching mask.

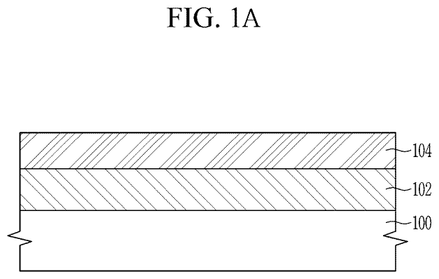

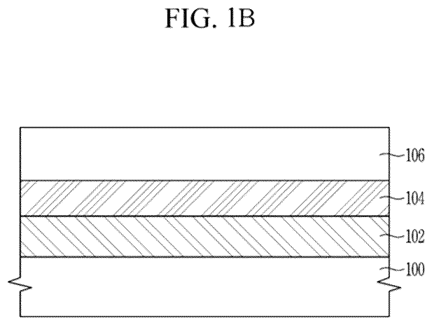

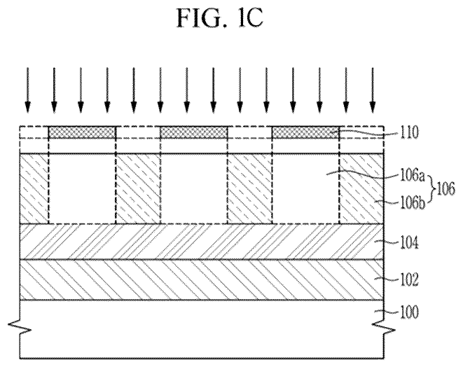

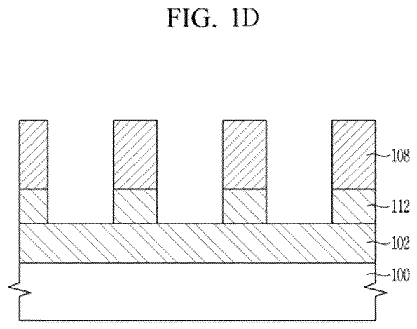

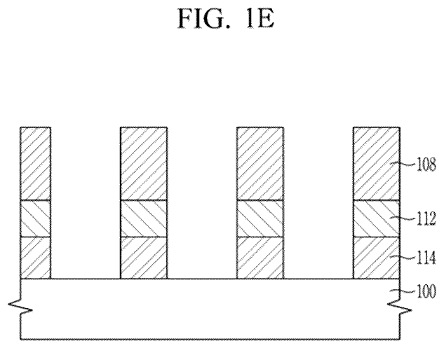

Hereinafter, a method of forming patterns using the semiconductor photoresist composition is described by referring to FIGS. 1A-1E. FIGS. 1A-1E are cross-sectional views for explaining a method of forming patterns using a semiconductor photoresist composition according to some example embodiments.

Referring to FIG. 1A, an object for etching is prepared. The aspect for etching may be a thin film 102 formed on a semiconductor substrate 100. Hereinafter, as an example, the object for etching is limited to the thin film 102. A surface of the thin film 102 is washed to remove impurities and/or the like remaining thereon. The thin film 102 may be for example a silicon nitride layer, a polysilicon layer, or a silicon oxide layer.

Subsequently, the resist underlayer composition for providing a resist underlayer 104 is spin-coated on the surface of the washed thin film 102. However, one or more embodiments are not limited thereto, and one or more suitable coating methods, for example, a spray coating, a dip coating, a knife edge coating, a printing method (for example, an inkjet printing and/or a screen printing), and/or the like may be used.

In some embodiments, the coating process of the resist underlayer may not be provided. Hereinafter, as an example, a process including the coating of the resist underlayer is described.

Then, the coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity and pattern formability of a photoresist line width if (e.g., when) a ray reflected from the interface between the substrate 100 and the photoresist layer 106 or a hard mask between layers is scattered into an unintended photoresist region.

Referring to FIG. 1B, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

In some embodiments, the formation of a pattern by using the semiconductor photoresist composition may include coating the semiconductor resist composition on the substrate 100 having the thin film 102 through spin coating, slit coating, inkjet printing, and/or the like and then, drying it to form the photoresist layer 106.

The semiconductor photoresist composition has already been illustrated in more detail and will not be illustrated again.

Subsequently, the substrate 100 having the photoresist layer 106 is subjected to a first baking process. The first baking process may be performed at about 80° C. to about 120° C.

Referring to FIG. 1C, the photoresist layer 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like as well as light having a wavelength such as an i-line (a wavelength of about 365 nm), a KrF excimer laser (a wavelength of about 248 nm), an ArF excimer laser (a wavelength of about 193 nm), and/or the like.

Light for the exposure according to some example embodiments may have a wavelength in a range of about 5 nm to about 150 nm or a high energy wavelength, for example, EUV (extreme ultraviolet; a wavelength of 13.5 nm), an E-Beam (an electron beam), and/or the like.

The exposed region 106b of the photoresist layer 106 has a different solubility from the unexposed region 106a of the photoresist layer 106 by forming a polymer through a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist layer 106 becomes indissoluble (e.g., easily indissoluble) by a developer due to the second baking process.

In FIG. 1D, the unexposed region 106a of the photoresist layer is dissolved and removed using the developer to form a photoresist pattern 108. For example, the unexposed region 106a of the photoresist layer is dissolved and removed by using an organic solvent such as 2-heptanone and/or the like to complete the photoresist pattern 108 corresponding to the negative tone image.

As described above, a developer used in a method of forming patterns according to some example embodiments may be an organic solvent. The organic solvent used in the method of forming patterns according to some example embodiments may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, and/or a (e.g., any suitable) combination thereof.

However, the photoresist pattern according to some example embodiments is not necessarily limited to the negative tone image but may be formed to have a positive tone image. Herein, a developer used for forming the positive tone image may be a quaternary ammonium hydroxide composition such as tetraethylammonium hydroxide, tetrapropylammonium hydroxide, tetrabutylammonium hydroxide, and/or a (e.g., any suitable) combination thereof.

As described above, exposure to light having a high energy such as EUV (extreme ultraViolet; a wavelength of 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness (e.g., width) of about 5 nm to about 100 nm. For example, the photoresist pattern 108 may have a width of a thickness (e.g., width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

Also, the photoresist pattern 108 may have a pitch with a half-pitch of less than or equal to about 50 nm, for example, less than or equal to about 40 nm, less than or equal to about 30 nm, less than or equal to about 20 nm, or less than or equal to about 10 nm, and a line width roughness of less than or equal to about 5 nm, less than or equal to about 3 nm, less than or equal to about 2 nm, or less than or equal to about 1 nm.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be for example dry etching using an etching gas and the etching gas may be for example CHF₃, CF₄, Cl₂, BCl₃ and a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of about 5 nm to about 100 nm which is equal to or substantially equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm. In an embodiment, a width of less than or equal to about 20 nm, the same or substantially the same as that of the photoresist pattern 108. For example, in the exposure process using an EUV light source, the thin film pattern formed by the photoresist pattern will have a width corresponding to that of the photoresist pattern. The width of the thin film pattern can range from about 5 nm to about 100 nm, with specific examples including ranges such as 5 nm to 90 nm, 5 nm to 80 nm, or so on, down to 5 nm to 20 nm. In some embodiments, the width may be less than or equal to about 20 nm, matching the width of the photoresist pattern.

Hereinafter, the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

In a 250 mL Schrank flask, t-butylSn(NEt₂)₃ (0.0765 mol, 30.00 g) and 150 mL of diethylether were added and then, cooled to −20° C. by using dry ice. N-methyl-acetamide (0.2677 mol, 17.57 g) was added thereto and then, slowly heated to room temperature. After refluxing by heating for 2 hours, by removing the solvent and volatile components under a reduced pressure, a compound represented by Chemical Formula 2 was obtained at a yield of 98%.

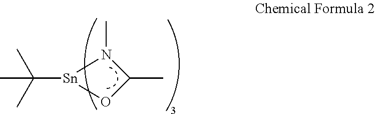

### Synthesis Example 2

In a 250 mL Schrank flask, iPr₂Sn(NEt₂)₂ (0.0859 mol, 30.00 g) and 150 mL of diethylether were added and then, cooled to −20° C. by using dry ice. N-methyl-acetamide (0.3007 mol, 17.57 g) was added thereto and then, slowly heated to room temperature. After refluxing by heating for 2 hours and then, by removing the solvent and volatile components under a reduced pressure, a compound represented by Chemical Formula 3 was obtained at a yield of 87%.

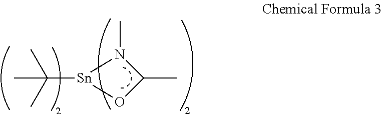

### Synthesis Example 3

In a 250 mL Schrank flask, iPrSn(NEt₂)₃ (0.0793 mol, 30.00 g) and 150 ml of diethylether were added and then, cooled to −20° C. by using dry ice. N-methyl-acetamide (0.2776 mol, 20.29 g) was added thereto and then, slowly heated to room temperature. After refluxing by heating for 2 hours and then, by removing the solvent and volatile components under a reduced pressure, a compound represented by Chemical Formula 4 was obtained at a yield of 91%.

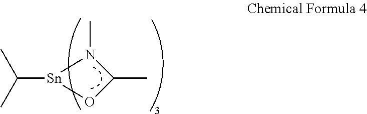

### Synthesis Example 4

In a 250 mL Schrank flask, nBuSn(NEt₂)₃ (0.0765 mol, 30.00 g) and 150 mL of diethylether were added and then, cooled to −20° C. by using dry ice. N-methyl-acetamide (0.2776 mol, 20.29 g) was added thereto and then, slowly heated to room temperature. After refluxing by heating for 2 hours and then, by removing the solvent and volatile components under a reduced pressure, a compound represented by Chemical Formula 5 was obtained at a yield of 91%.

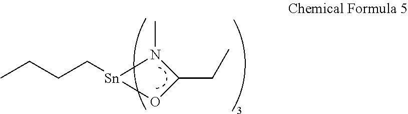

### Comparative Synthesis Example 1

40.7 g of t-butylSnPh₃ and 300 g of propionic acid were added to a 250 mL two-necked round-bottom flask and heated under reflux for 24 hours.

Unreacted propionic acid was removed under reduced pressure to obtain a compound represented by Chemical Formula 7.

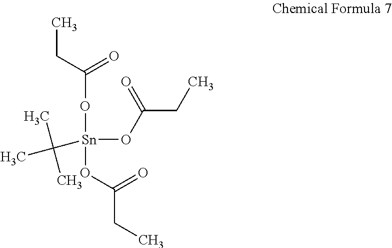 [SMILES: CCC(=O)[O][Sn]([O]C(=O)CC)([O]C(=O)CC)[C](C)(C)C]

### Comparative Synthesis Example 2

In a 1 L round-bottomed flask, 400 mL of anhydrous diethylether was added to 40.33 g of (t-Amyl)₄Sn and after maintaining a temperature at −30° C., 78.155 g of SnCl₄ was slowly added thereto in a dropwise fashion. The temperature was slowly increased for 1 hour or more to room temperature. After stirring at the room temperature for 2 days under a nitrogen atmosphere and cooling again to −30° C., 78.15 g of sodium ethoxide was slowly added dropwise thereto, while being careful not to cause rapid heat. After slowly increasing the temperature to room temperature and stirring at the room temperature for 3 hr to terminate the reaction, the resultant was filtered, concentrated, and vacuum-dried, obtaining a compound represented by Chemical Formula 8 at a yield of 62%.

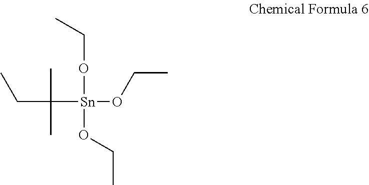

### Preparation of Semiconductor Photoresist Compositions

### Examples 1 to 4 and Comparative Examples 1 and 2

Each of the compounds according to Synthesis Examples 1 to 4 and Comparative Synthesis Examples 1 and 2 was dissolved in propylene glycol monomethyl ether acetate (PGMEA) at 3 wt % and then, filtered with a 0.1 μm PTFE syringe filter to prepare a photoresist composition.

### Evaluation 1: Storage Stability Evaluation

The organometallic compounds used in Examples 1 to 4 and Comparative Examples 1 and 2 were evaluated with respect to storage stability according to the following criteria, and the results are shown in Table 1.

### Storage Stability

Each of the semiconductor photoresist compositions according to Examples 1 to 4 and Comparative Examples 1 and 2 was examined with naked eyes for a degree of precipitation when allowed to stand under the condition of room temperature (20±5° C.) and then, evaluated according to the following storage criteria based on how long it took for precipitation to be observed.

### Evaluation Criteria

⊚: Can be stored for more than 4 months
∘: Can be stored for 3 months or more but less than 4 months
Δ: Can be stored for less than 3 months but more than 2 weeks or more
X: Can be stored for less than 2 weeks

### Evaluation 2: Coating Performance Evaluation

Each of the photoresist compositions according to Examples 1 to 4 and Comparative Examples 1 and 2 was spin-coated on a wafer at 1500 rpm for 60 seconds and baked at 110° C. for 60 seconds to form a thin film, which was imaged with an atomic force microscopy (AFM) and/or the like, and the image was used to measure surface roughness of the thin film according to the following reference by using a software (ex. Optical Profiler), and the results are shown in Table 1.

For the surface roughness, R_{q} refers to root mean square (rms) roughness of vertical values (e.g., heights) in the surface profile with reference to the mean line.

### Evaluation Criteria

⊚: Rq is less than or equal to 0.3 nm
∘: Rq is greater than 0.3 nm and less than or equal to 0.4 nm
X: Rq is greater than 0.4 nm

### Evaluation 3: Delay Characteristic Evaluation

Each of the photoresist compositions according to Examples and Comparative Examples was spin-coated for 30 seconds at 1500 rpm, respectively, on a 200 mm circular silicon wafer whose surface was deposited with HMDS, baked at 100° C. to 120° C. for 60 seconds (it was baked after the application (post-apply bake, PAB)), and left at room temperature (23±2° C.) for 10 minutes, which is the process delay evaluation time.

Subsequently, a straight line array of 50 circular pads with a diameter of 500 μm was formed on (e.g., projected onto) each wafer (on which the composition for a photoresist was coated) by using EUV light (Lawrence Berkeley National Laboratory Micro Exposure Tool, MET). Pad exposure time was adjusted to ensure that the EUV light in an increased dose was applied to each pad.

Then, the resist and substrate were exposed to temperatures between 160° C. and 200° C. on a hot plate for 60 seconds and 180 seconds, and then baked. The baked film was developed with a PGMEA solvent to form a negative tone image. Finally, the obtained film was baked again at 150° C. for 2 minutes on the hot plate, thereby completing the process.

The resist was measured with respect to line widths formed by exposure with an equal dose (energy) by using critical dimension (CD)-SEM. A difference in the resist line widths (ΔCD), formed under different process delay times (0 minute, and 10 minutes post-coating delay (PCD)), was calculated to assess the impact of delay time on the resist line widths.

### Evaluation Criteria

⊚: ΔCD greater than 2% and less than or equal to 7%
∘: ΔCD greater than 7% and less than or equal to 15%
X: ΔCD greater than 15%

TABLE 1

| | | | Coating | |
|---|---|---|---|---|
| | | | Performance | Delay |
| | Organometallic | Storage | (=surface | charac- |
| | compound | stability | roughness) | teristics |
| Example 1 | Chemical Formula 2 | Δ | ◯ | ◯ |
| Example 2 | Chemical Formula 3 | ◯ | ◯ | ⊚ |
| Example 3 | Chemical Formula 4 | ⊚ | ⊚ | ⊚ |
| Example 4 | Chemical Formula 5 | ⊚ | ⊚ | ◯ |
| Comparative | Chemical Formula 7 | ⊚ | X | ◯ |
| Example 1 | | | | |
| Comparative | Chemical Formula 8 | X | ⊚ | X |
| Example 2 | | | | |

From the results in Table 1, the patterns formed using the semiconductor photoresist compositions according to Examples 1 to 4 have excellent or suitable storage stability, coatability, and delay characteristics compared to Comparative Examples 1 and 2.

It will be understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. As used herein, the term “combination thereof” refers to a mixture, a laminate, a composite, a copolymer, an alloy, a blend, a reaction product, and/or the like of the constituents.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A device of forming patterns, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinbefore, the certain embodiments have been described and illustrated, however, it is apparent to a person with ordinary skill in the art that the present disclosure is not limited to one or more embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Reference Numerals

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A semiconductor photoresist composition, comprising
an organometallic compound represented by Chemical Formula 1; and
a solvent: 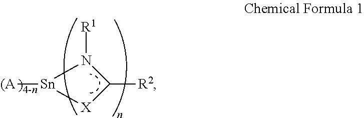
wherein, in Chemical Formula 1,
A is selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X is O or S,
R¹ and R² are each independently selected from among hydrogen; a substituted or unsubstituted C1 to C20 alkyl group; a substituted or unsubstituted C2 to C20 alkenyl group; a substituted or unsubstituted C2 to C20 alkynyl group; a substituted or unsubstituted C3 to C20 cycloalkyl group; a substituted or unsubstituted C3 to C20 cycloalkenyl group; a substituted or unsubstituted C6 to C30 aryl group; a substituted or unsubstituted C7 to C30 arylalkyl group; and L-Z—R³, L being a substituted or unsubstituted C1 to C20 alkylene group, Z being O, S, or NR⁴, and R³ and R⁴ being each independently a C1 to C20 alkyl group, and
n is an integer of 2 or 3.

2. The semiconductor photoresist composition as claimed in claim 1, wherein
A is selected from among a substituted or unsubstituted C1 to C10 alkyl group, a substituted or unsubstituted C2 to C20 heteroalkyl group, a substituted or unsubstituted C3 to C12 cycloalkyl group, a substituted or unsubstituted C2 to C20 heterocycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C2 to C20 heteroaryl group, a substituted or unsubstituted C7 to C20 arylalkyl group, a substituted or unsubstituted C4 to C20 heteroarylalkyl group, and a substituted or unsubstituted C1 to C20 alkylcarbonyl group.

3. The semiconductor photoresist composition as claimed in claim 1, wherein
A is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, substituted or unsubstituted tert-pentyl group, a substituted or unsubstituted 1-methylpropyl group, a substituted or unsubstituted 1,1-dimethylpropyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

4. The semiconductor photoresist composition as claimed in claim 1, wherein
R¹ and R² are each independently selected from among hydrogen; a substituted or unsubstituted C1 to C10 alkyl group; a substituted or unsubstituted C2 to C10 alkenyl group; a substituted or unsubstituted C2 to C10 alkynyl group; a substituted or unsubstituted C3 to C12 cycloalkyl group; a substituted or unsubstituted C3 to C12 cycloalkenyl group; a substituted or unsubstituted C6 to C20 aryl group; a substituted or unsubstituted C7 to C20 arylalkyl group; and L-Z—R³, L being a substituted or unsubstituted C1 to C10 alkylene group, Z being O, S, or NR⁴, and R³ and R⁴ being each independently C1 to C10 alkyl group.

5. The semiconductor photoresist composition as claimed in claim 1, wherein
R¹ and R² are each independently selected from among hydrogen, a substituted or unsubstituted C1 to C10 alkyl group, a substituted or unsubstituted C3 to C12 cycloalkyl group, a substituted or unsubstituted C2 to C10 alkenyl group, a substituted or unsubstituted C6 to C20 aryl group, and a substituted or unsubstituted C7 to C20 arylalkyl group.

6. The semiconductor photoresist composition as claimed in claim 1, wherein
the organometallic compound represented by Chemical Formula 1 is any one selected from among compounds listed in Group 1:

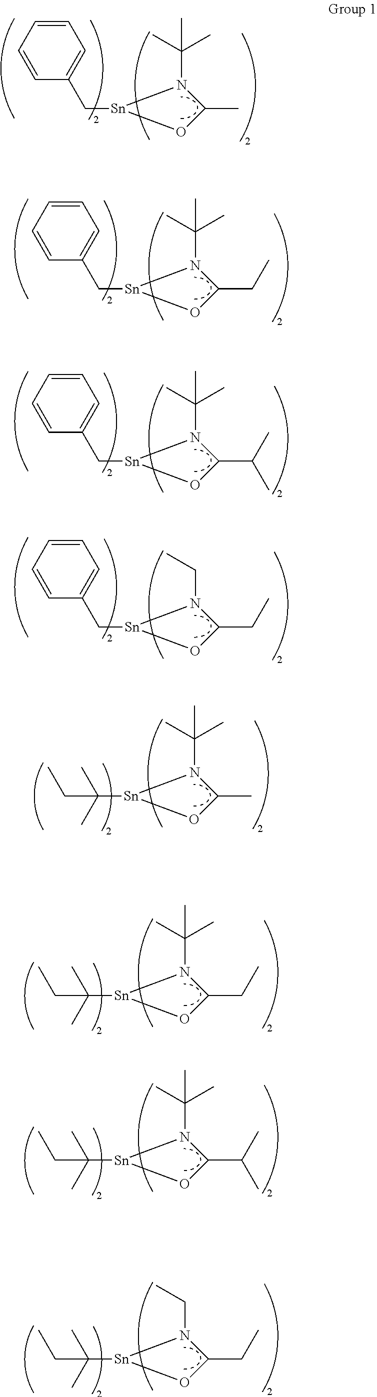

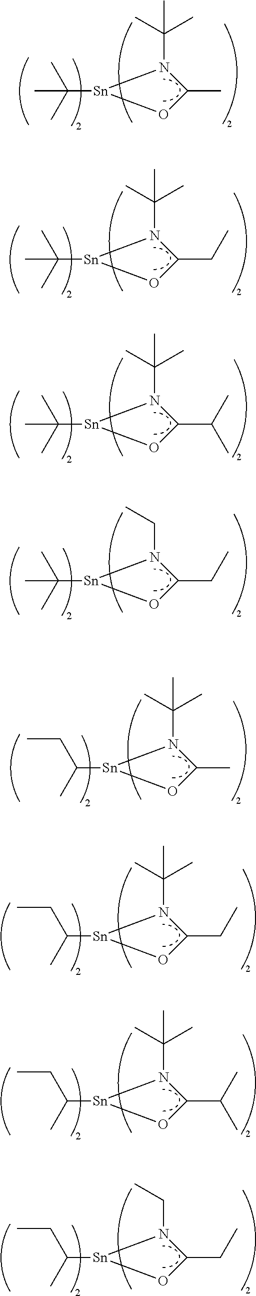

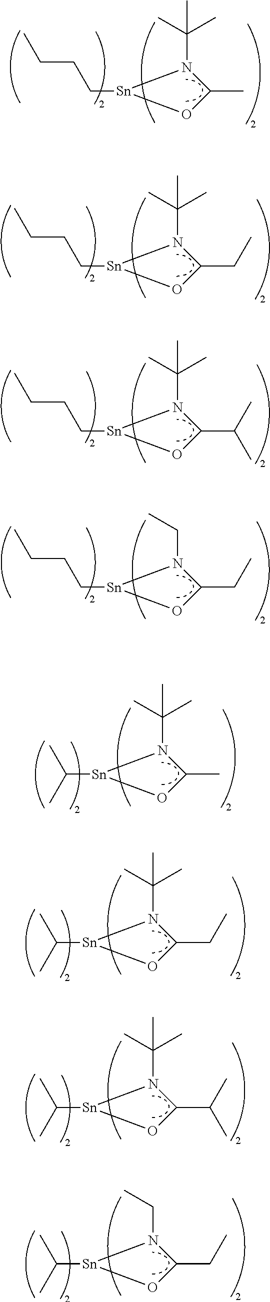

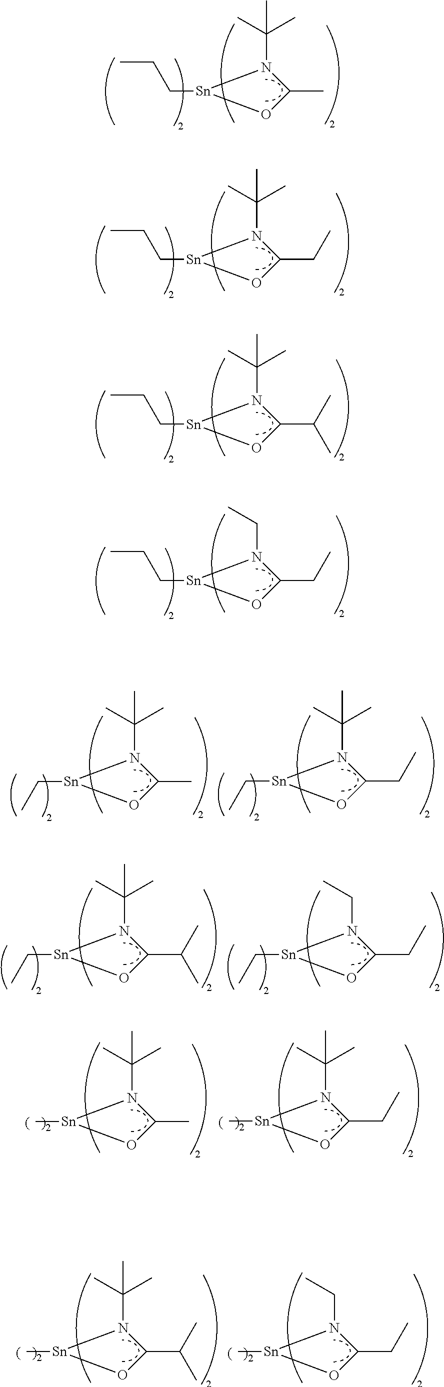

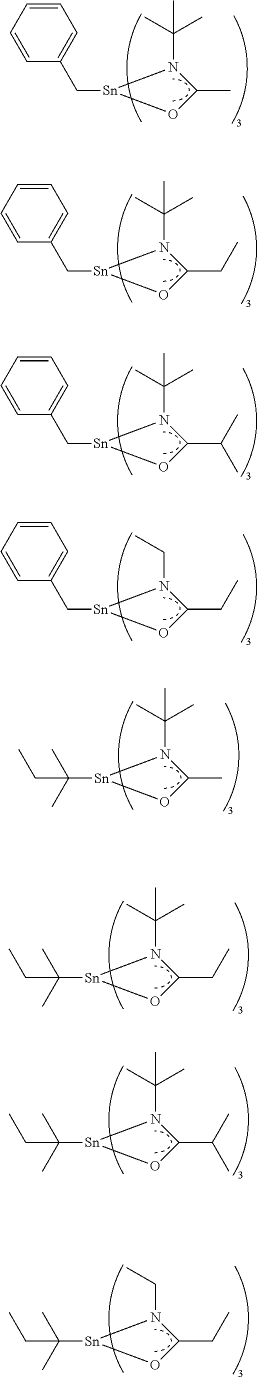

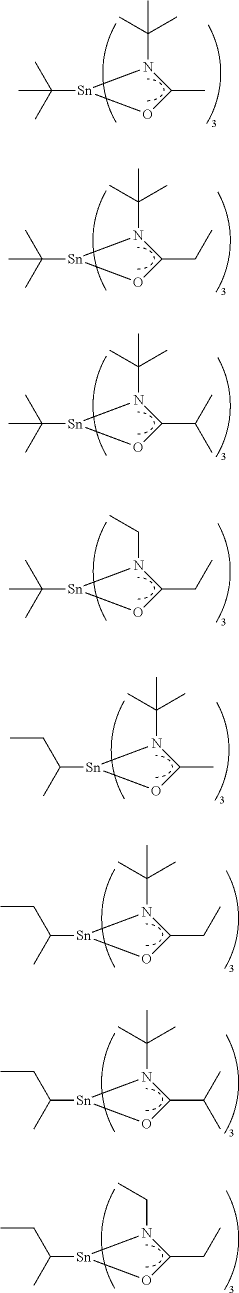

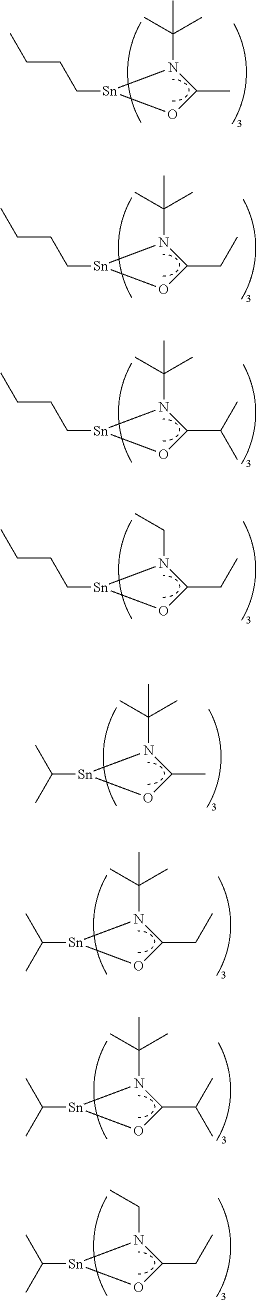

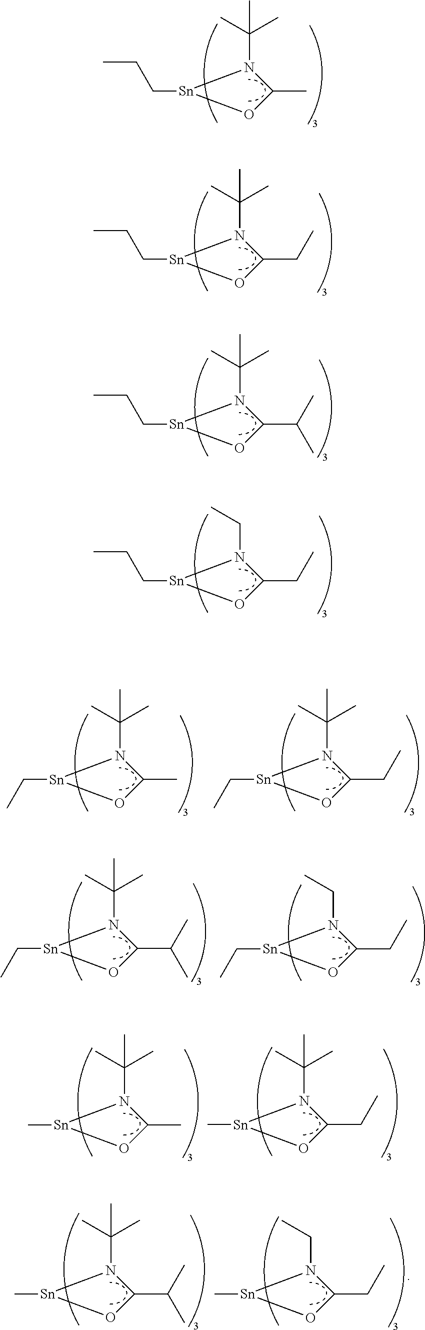

7. The semiconductor photoresist composition as claimed in claim 1, wherein
the organometallic compound is about 0.5 wt % to about 30 wt % in amount based on 100 wt % of the semiconductor photoresist composition.

8. The semiconductor photoresist composition as claimed in claim 1, wherein
the semiconductor photoresist composition further comprises an additive selected from among a surfactant, a crosslinking agent, a leveling agent, an organic acid, a quencher, and a combination thereof.

9. A method comprising:
coating the semiconductor photoresist composition as claimed in claim 1 on an etching-objective layer to form a photoresist layer;
patterning the photoresist layer to form a photoresist pattern; and
etching the etching-objective layer utilizing the photoresist pattern as an etching mask,
wherein the method is a method of forming patterns.

10. The method as claimed in claim 9, wherein
in the patterning of the photoresist layer, light with a wavelength of about 5 nm to about 150 nm is utilized.

11. The method as claimed in claim 9, wherein
the photoresist pattern has a width of about 5 nm to about 100 nm.

12. The method as claimed in claim 9, further comprising
forming an etching-objective layer on a substrate.
